(19) United States
(12) Patent Application Publication
(10) Pub. No.: US 2003/0065996 A1
(43) Pub. Date: Apr. 3, 2003

(54) Test circuit for semiconductor memory and semiconductor memory device

(75) Inventors: Yutaka Shimada, Tokyo (JP); Yoshinori Fujiwara, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/118,966

(22) Filed: Apr. 10, 2002

(30) Foreign Application Priority Data
Jul. 25, 2001 (JP) 2001-224900

(51) Int. Cl. G11C 29/00

(52) U.S. Cl. 714/718

(57) ABSTRACT

According to the present invention, a pseudo-error signal generating circuit is provided between a memory circuit and a self-test circuit. The pseudo-error signal generating circuit converts an output signal of the memory circuit based on a setting signal to supply a pseudo-error signal necessary to verify the operation of the self-test circuit. The pseudo-error signal generating circuit has a scan chain circuit in which a setting signal is set, and generates a pseudo-error signal based on the setting signal.

### BACKGROUND OF THE INVENTION

1. Field of the Invention

The present invention relates to a test circuit for a semiconductor memory having a self-test circuit, and to a semiconductor memory device having a memory circuit and a self-test circuit. In particular, the present invention relates to a test circuit for a semiconductor memory and to a semiconductor memory device, wherein the operation verification of a self-test circuit does not affect a memory circuit.

2. Background Art

Two known self-test circuits for a memory circuit are the built-in self-test circuit (BIST circuit) and the built-out self-test circuit (BOST circuit). These self-test circuits have a function to receive a test output from the memory circuit and perform an operation test on the memory circuit within or near the semiconductor memory device having the memory circuit therein. The BIST circuit is formed on a semiconductor memory chip on which the memory circuit is formed, or alternatively it is formed on another chip mounted on the package on which the memory chip is mounted. The BOST circuit is mounted on a test performance board disposed near the semiconductor memory device.

Incidentally, it is also necessary to verify the operation of these self-test circuits. To perform the operation verification, pseudo-error signals must be supplied to the self-test circuits. However, there has been no effective means for generating these pseudo-error signals to date.

### SUMMARY OF THE INVENTION

The present invention proposes a novel test circuit for a semiconductor memory having a pseudo-error signal generating circuit to generate pseudo-error signals.

Furthermore, the present invention proposes a novel semiconductor memory device having a memory circuit, a self-test circuit, and a built-in pseudo-error signal generating circuit.

According to one aspect of the present invention, in a test circuit for a semiconductor memory, the test circuit includes a built-out self-test circuit connected to a memory circuit of semiconductor memory, the built-out self-test circuit receiving an output signal of the memory circuit to test the memory circuit, and a pseudo-error signal generating circuit provided between the memory circuit and the self-test circuit. The pseudo-error signal generating circuit generates a pseudo-error signal by converting an output signal of the memory circuit to verify operation of the built-out self-test circuit. Accordingly, the operation of built-out the self-test circuit can be easily verified without adversely affecting the memory circuit.

According to another aspect of the present invention, a semiconductor memory device includes a memory circuit, a self-test circuit connected to the memory circuit, and a pseudo-error signal generating circuit provided between the memory circuit and the self-test circuit. The pseudo-error signal generating circuit generates a pseudo-error signal by converting an output signal of the memory circuit to verify operation of the self-test circuit. Accordingly, the operation of the self-test circuit can be easily verified without adversely affecting the memory circuit.

Other and further objects, features and advantages of the invention will appear more fully from the following description.

### BRIEF DESCRIPTION OF THE DRAWINGS

FIG. 1 is a block circuit diagram showing a first embodiment of a test circuit for a semiconductor memory according to the present invention;

FIG. 2 is an explanatory diagram schematically showing the scan chain circuit 31;

FIG. 3 shows a specific example of the scan chain circuit 31;

FIG. 4 shows the output trigger circuit 50;

FIG. 5 is a test timing chart of the scan chain circuit 31 according to the first embodiment;

FIG. 6 is an explanatory diagram indicating the operation of the scan chain circuit 31 corresponding to FIG. 5;

FIG. 7 shows the entire test timing of the first embodiment;

FIG. 8 is a flowchart showing the entire test flow of the first embodiment;

FIG. 9 is a circuit diagram showing a scan chain circuit 31A used by a second embodiment of the test circuit for a semiconductor memory according to the present invention;

FIG. 10 is a block circuit diagram showing a third embodiment of the test circuit for a semiconductor memory according to the present invention;

FIG. 11 is a block circuit diagram showing a fourth embodiment of the test circuit for a semiconductor memory according to the present invention;

FIG. 12 is a block circuit diagram showing a fifth embodiment of the test circuit for a semiconductor memory according to the present invention;

FIG. 13 is a block circuit diagram showing a sixth embodiment of the test circuit for a semiconductor memory according to the present invention.

FIG. 14 is a block circuit diagram showing a seventh embodiment of the test circuit for a semiconductor memory according to the present invention.

FIG. 15 is a block circuit diagram showing an eighth embodiment of the test circuit for a semiconductor memory according to the present invention.

### DETAILED DESCRIPTION OF THE PREFERRED EMBODIMENTS

### First Embodiment

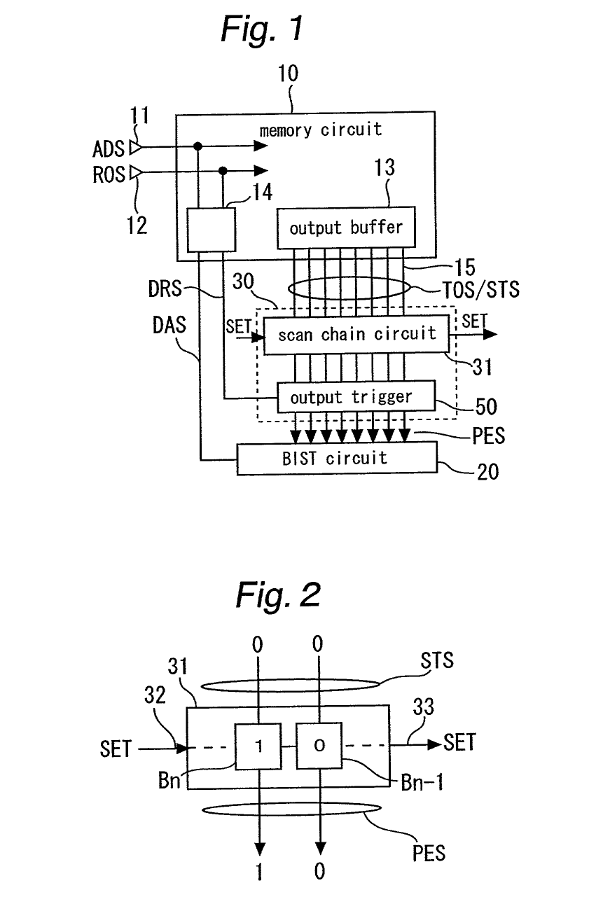

FIG. 1 is a block circuit diagram showing a first embodiment of a test circuit for a semiconductor memory according to the present invention. This first embodiment also indicates a first embodiment of a semiconductor memory device of the present invention. The test circuit for a semiconductor memory shown in FIG. 1 is a semiconductor memory device having a single-chip configuration in which a semiconductor memory circuit 10, a BIST circuit 20, and a pseudo-error signal generating circuit 30 are formed on a semiconductor chip. The memory circuit 10 is made of DRAMs, SRAMs, etc., and has input terminals 11 and 12 for an address signal ADS and a read-out signal ROS respectively. The memory circuit 10 also has an output buffer 13 and an output terminal 15 connected to the outputting portion of the output buffer 13. The output terminal 15 is n-bit wide, for example, 8-bit wide. The memory circuit 10 further has a delay circuit 14 which receives the address signal ADS and the read-out signal ROS and generates a delay address signal DAS and a delay read-out signal DRS.

The BIST circuit 20 receives a test output from the memory circuit 10 and analyzes the operation of the memory circuit 10. This operation analysis includes, for example, the analysis for checking the operation of a large number of memory elements included in the memory circuit 10 and replacing defective memory elements with redundant circuits. When the memory circuit 10 is tested, an address signal ADS and a read-out signal ROS for the test are supplied to the memory circuit 10 which in turn outputs an output signal, that is, a test output TOS, from its output terminal 15 to the BIST circuit 20. The BIST circuit 20 analyzes the test output TOS.

The pseudo-error signal generating circuit 30 is effectively used when verifying the operation of the BIST circuit 20. The pseudo-error signal generating circuit 30 receives a standard test signal STS, converts it into a pseudo-error signal PES, and supplies the pseudo-error signal PES to the BIST circuit 20. The pseudo-error signal PES is used to verify the operation of the BIST circuit 20. The standard test signal STS is a standard test pattern output from the memory circuit 10 as a test output TOS. For example, the signal which the values of all of the bits are “0”, that is, “00000000” in the case of the 8 bits, is used as the standard test signal STS. The pseudo-error signal PES is obtained as a result of converting the value of some of the bits included in the standard test signal STS to “1”, for example, the signal “10101010”. This pseudo-error signal PES is supplied to the BIST circuit 20, and the analysis results output from the BIST circuit 20 are checked. Since the supplied pseudo-error signal PES is known, the analysis output of the BIST circuit 20 is checked with respect to this known pseudo-error signal PES to verify the operation of the BIST circuit 20.

The pseudo-error signal generating circuit 30 includes a scan chain circuit 31 and an output trigger circuit 50. A setting signal SET is supplied to the scan chain circuit 31. The standard test signal STS is converted based on this setting signal SET to produce the pseudo-error signal PES. The output trigger circuit 50 outputs the produced pseudo-error signal PES to the BIST circuit 20 at a predetermined timing.

FIG. 2 is an explanatory diagram schematically showing the scan chain circuit 31. The scan chain circuit 31 has an input terminal 32 and an output terminal 33 for the setting signal SET. FIG. 2 indicates the representative two bits Bn and Bn−1 of the scan chain circuit 31. Assume that the setting signal SET is currently set so that the bit Bn and the bit Bn−1 are to be set at “1” and “0”, respectively. The current value “0” of the bit Bn is converted to “1”, while the current value “0” of the bit Bn-1 is output as it is. Thus, the test standard signal STS, which is a test output TOS, is converted based on the setting signal SET to produce the pseudo-error signal PES. Since the pseudo-error signal PES can be changed by changing the setting signal SET, it is possible to generate a desired pseudo-error signal PES.

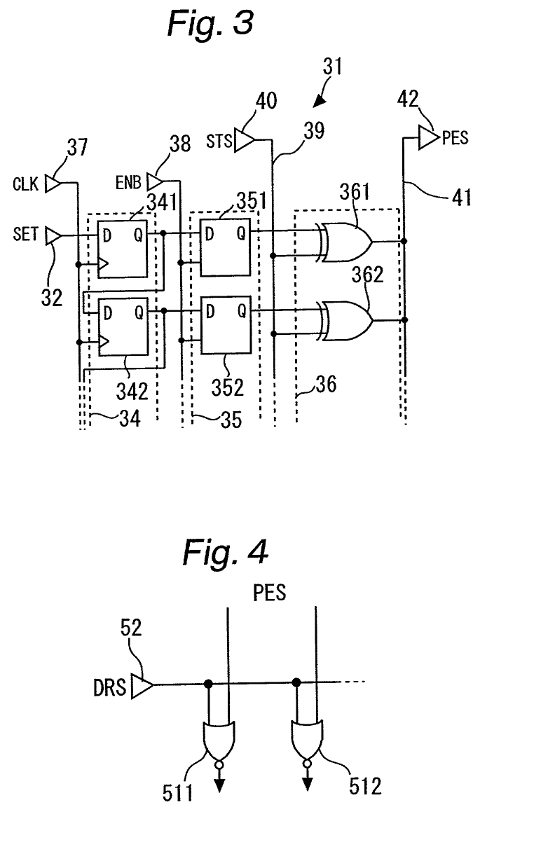

FIG. 3 shows a specific example of the scan chain circuit 31. Even though FIG. 3 shows only its upper two bits, the remaining bits are configured in the same way as the upper two bits. The scan chain circuit 31 has a scan chain 34, a half latch 35, and a logic circuit 36. The scan chain 34 has DQ flip-flops 341, 342, and so on, each corresponding to one of the n bits. The D input terminal of the DQ flip-flop 341 is connected to the input terminal 32 for the setting signal SET, while its Q output terminal is connected to the D input terminal of the following DQ flip-flop 342. The Q output terminal of the DQ flip-flop 342 is connected to the D input terminal of the following DQ flip-flop. Thus, the Q output terminal of each flip-flop is connected to the D input terminal of the subsequent flip-flop in a series manner. A common clock signal CLK is supplied from an input terminal 37 to the DQ flip-flops 341, 342, and so on, in the scan chain 34.

The half latch 35 also has DQ flip-flops 351, 352, and so on, each corresponding to one of the n bits. The D input terminal of each of the DQ flip-flops 351, 352, and so on, in the half latch 35 is connected to the Q output terminal of the respective one of the DQ flip-flops 341, 342, and so on, in the scan chain 34. Each of the DQ flip-flops 351, 352, and so on, in the half latch 35 is connected to the input terminal 38 for a common enable signal ENB. When the setting signal SET is set in the scan chain 34, the setting signal SET is input from the input terminal 32 sequentially toward the output terminal 33 in synchronization with the clock CLK. Then, by use of the enable signal ENB, the output from the Q output terminals of the DQ flip-flops 341, 342, and so on, in the scan chain 34 is set in the DQ flip-flops 351, 352, and so on, in the half latch 35. If the setting signal SET set in the DQ flip-flops 341, 342, and so on, in the scan chain 34 is “01010101”, this specific setting signal is set in the DQ flip-flops 351, 352, and so on, in the half latch 35.

The logic circuit 36 of the scan chain circuit 31 includes exclusive OR circuits 361, 362, and so on, each corresponding to one of the n bits. One input of each of the exclusive OR circuits 361, 362, and so on, is connected to the Q output of respective one of the DQ flip-flops 351, 352, and so on, in the half latch 35. The other input terminal of each of the exclusive OR circuits 361, 362, and so on, is connected to an input terminal 40 through a bus line 39. The input terminal 40 is connected to the output terminal 15 of the memory circuit 10, and receives the standard test signal STS from the memory circuit 10. Furthermore, the output terminal of each of the exclusive OR circuits 361, 362, and so on, is connected to an output terminal 42 of the scan chain circuit 31 through a bus line 41, and the pseudo-error signal PES is generated on the output terminal 42. The logic circuit 36 converts the standard test signal STS received from the memory circuit 10 based on the setting signal SET to produce the pseudo-error signal PES. For example, if the setting signal SET set in the half latch 35 is “01010101” and the standard test signal is “00000000”, the pseudo-error signal PES output from the logic circuit 36 is “10101010”, which is the inverse of the setting signal SET and produced on the output terminal 42.

FIG. 4 shows the output trigger circuit 50. Even though FIG. 4 indicates only the circuit portions corresponding to representative two bits, the circuit portions for the remaining bits are also configured in the same way. The output trigger circuit 50 has NOR gates 511, 512, and so on, each corresponding to one of the n bits. The pseudo-error signal PES is supplied from the scan chain circuit 31 to one input of each of the NOR gates 511, 512, and so on. Specifically, the one input terminal of each of the NOR gates 511, 512, and so on, is connected to the output terminal of the respective one of the exclusive OR gates 361, 362, and so on, in the scan chain circuit 31. The other input terminal of each of the NOR gates 511, 512, and so on, is commonly connected to the input terminal 52 for the delay read-out signal DRS and receives supply of the delay read-out signal DRS from the delay circuit shown in FIG. 1. The output trigger circuit 50 outputs the pseudo-error signal PES to the BIST circuit 20 at the timing of receiving the delay read-out signal DRS.

When the memory circuit 10 is tested by the BIST circuit 20, the setting signal SET is so set that the test output TOS of the memory circuit 10 is output as it is. For example, each bit of the setting signal SET is set to “0”. In this case, the output trigger circuit 50 is configured so that its input terminal 52 directly receives the read-out signal ROS directed to the memory circuit 10 instead of receiving the delay read-out signal DRS. Furthermore, the test output TOS from the memory circuit 10 is not subjected to conversion and is supplied from the output trigger circuit 50 to the BIST circuit 20 immediately after it is read out from the memory circuit 10. The BIST circuit 20 analyzes the test output TOS.

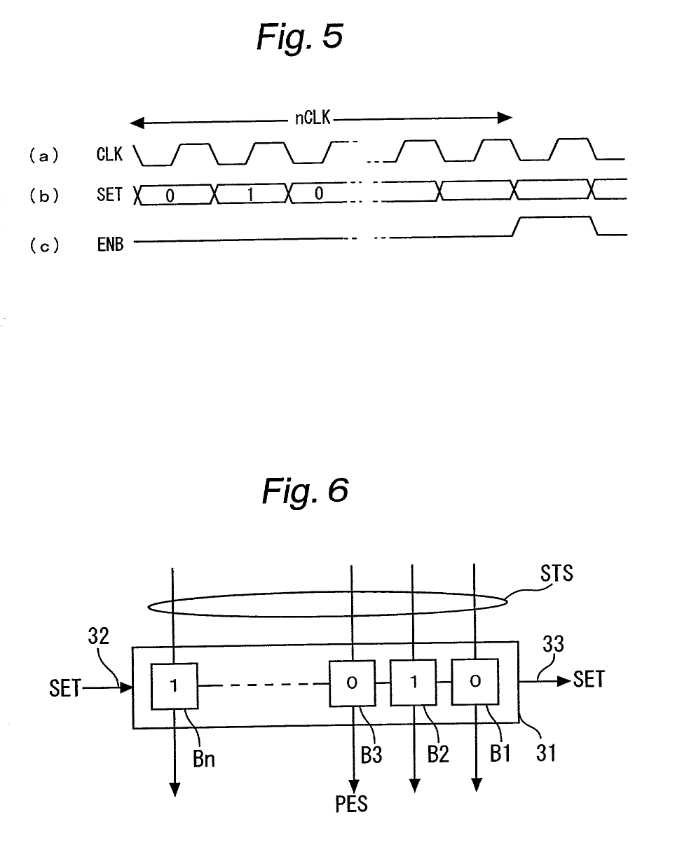

FIG. 5 is a test timing chart of the scan chain circuit 31 according to the first embodiment. Reference numeral (a) denotes the waveform of the clock signal CLK input to the input terminal 37 shown in FIG. 3; reference numeral (b) denotes the setting signal SET which is input from the input terminal 32 and corresponds to the clock signal CLK; and reference numeral (c) denotes the enable signal ENB which is input to the input terminal 38 and corresponds to the clock signal CLK and the setting signal SET. All of the horizontal axes for (a), (b), and (c) indicate the same time lapse. The setting signal SET is sequentially input in synchronization with the clock signal CLK. When n number of clock signals CLK have been entered, each of the n bits constituting the desired setting signal SET has been supplied to the respective one of the DQ flip-flops 341, 342, and so on, in the scan chain 34. Subsequently, the enable signal ENB rises, setting the setting signal SET in the DQ flip-flops 351, 352, and so on, in the half latch 35.

FIG. 6 is an explanatory diagram indicating the operation of the scan chain circuit 31 corresponding to FIG. 5. The setting signal SET is set in the n number of bits, namely B1, B2, . . . Bn, of the scan chain circuit 31. In this state, the standard test signal STS is input to the input terminal 40, generating the pseudo-error signal PES.

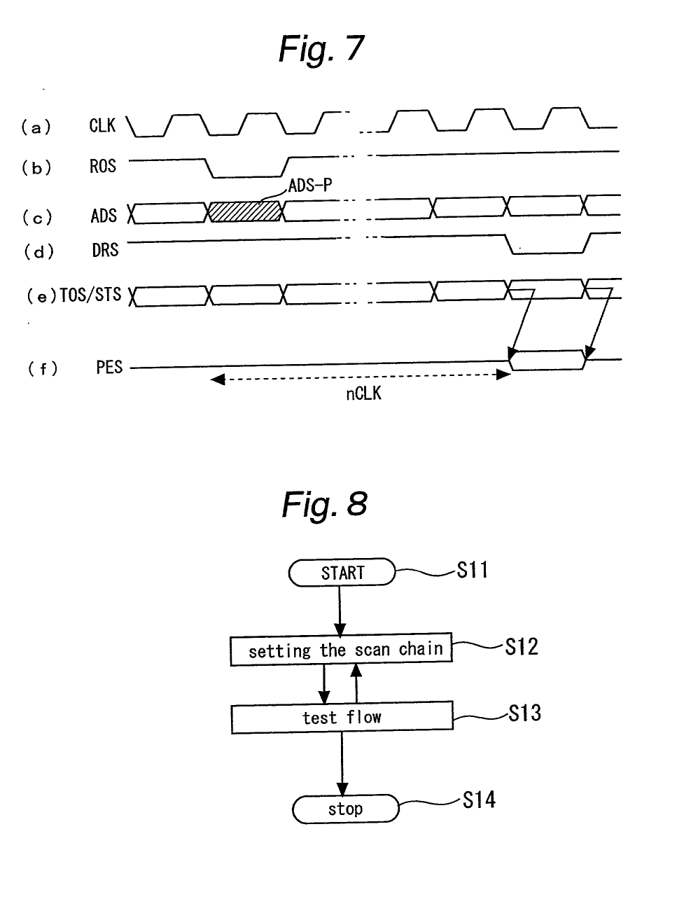

FIG. 7 shows the entire test timing of the first embodiment. In the figure, reference numeral (a) denotes a clock signal CLK commonly used for the entire circuit shown in FIG. 1. For example, this clock signal CLK is the same as the clock signal CLK shown in FIG. 5(a). Reference numeral (b) denotes the read-out signal ROS supplied to the read-out signal input 12 for the memory circuit 10; reference numeral (c) denotes the address signal ADS supplied to the address input 11 of the memory circuit 10; reference numeral (d) denotes the delay read-out signal DRS supplied to the input terminal 52 of the output trigger circuit 50; reference numeral (e) denotes the test output signals TOS and STS from the memory circuit 10; and reference numeral (f) denotes the pseudo-error signal PES supplied to the BIST circuit 20. The horizontal axis for each signal indicates the same time lapse.

A setting is made so that the pseudo-error signal PES to be produced corresponds to a desired address signal ADS-P to be generated. With this arrangement, the read-out signal ROS is caused to fall so that the test output TOS output from the memory circuit 10 is the standard test signal STS corresponding to the above desired address signal ADS-P. The delay read-out signal DRS falls n clock signals after the generation of this standard test signal STS. At this timing, the standard test signal STS is converted to the pseudo-error signal PES based on the setting signal SET set in the scan chain circuit 31, and the obtained pseudo-error signal PES is supplied to the BIST circuit 20.

FIG. 8 is a flowchart showing the entire test flow of the first embodiment. In the first embodiment, the test flow starts at step S11, and a desired setting signal SET is set in the scan chain circuit 31 at step S12. Subsequently, at step S13, the standard test signal STS is converted to the pseudo-error signal PES based on the desired setting signal SET. The pseudo-error signal PES is supplied to the BIST circuit 20 to verify the operation of the BIST circuit 20. Step S13 is called “test flow step”. The BIST circuit 20 receives a test output from the memory circuit 10 and analyzes the operation of the memory circuit 10. This operation analysis includes, for example, the analysis for checking the operation of a large number of memory elements included in the memory circuit 10 and replacing defective memory elements with redundant circuits. In such an operation analysis, a plurality of memory elements to be tested are sequentially selected and analyzed. As a result, an optimum use of the redundant circuits is determined. To verify the operation of the BIST circuit 20 corresponding to the above operation analysis, it is necessary to supply pseudo-error signal patterns to the BIST circuit 20 while changing a plurality of pseudo-error signals sequentially. In the flowchart shown in Fig.8, it is possible to supply sequentially-changing pseudo-error signal patterns by repeating steps S12 and S13 a number of times as required. Step 14 is the test termination step.

As described above, the first embodiment employs the pseudo-error signal generating circuit 30 between the memory circuit 10 and the BIST circuit 20 in order to generate pseudo-error signals for verifying the operation of the BIST circuit 20. Furthermore, the pseudo-error signal generating circuit 30 converts the output signal STS of the memory circuit 10 to generate the pseudo-error signal PES. With this arrangement, it is possible to verify the operation of the BIST circuit 20 without adversely affecting the operation of the memory circuit 10.

Furthermore, since the BIST circuit 20 and the pseudo-error signal generating circuit 30 are formed on a chip on which the memory circuit 10 is formed, it is possible to miniaturize the BIST circuit 20 and the pseudo-error signal generating circuit 30 and verify the operation of the BIST circuit 20 within the single chip. In addition, the pseudo-error signal generating circuit 30 has the scan chain circuit 31, and the pseudo-error signal PES is generated by converting the output signal STS of the memory circuit 10 based on the setting signal SET set in the scan chain circuit 31. Therefore, it is possible to easily generate a desired pseudo-error signal PES by changing the setting signal SET. The logic gate circuit 36 is effective for converting the output signal STS of the memory circuit 10 based on the setting signal SET. Use of the logic gate circuit 36 makes it easy to convert the output signal STS of the memory circuit 10 based on the setting signal SET. The output trigger circuit 50 is effective for supplying the pseudo-error signal PES to the BIST circuit 20 at a proper timing.

Furthermore, it is possible to verify the operation of the BIST circuit 20 by use of a desired pseudo-error signal pattern obtained as a result of generating a plurality of pseudo-error signals PES while changing the setting signal SET set in the scan chain circuit 31.

### Second Embodiment

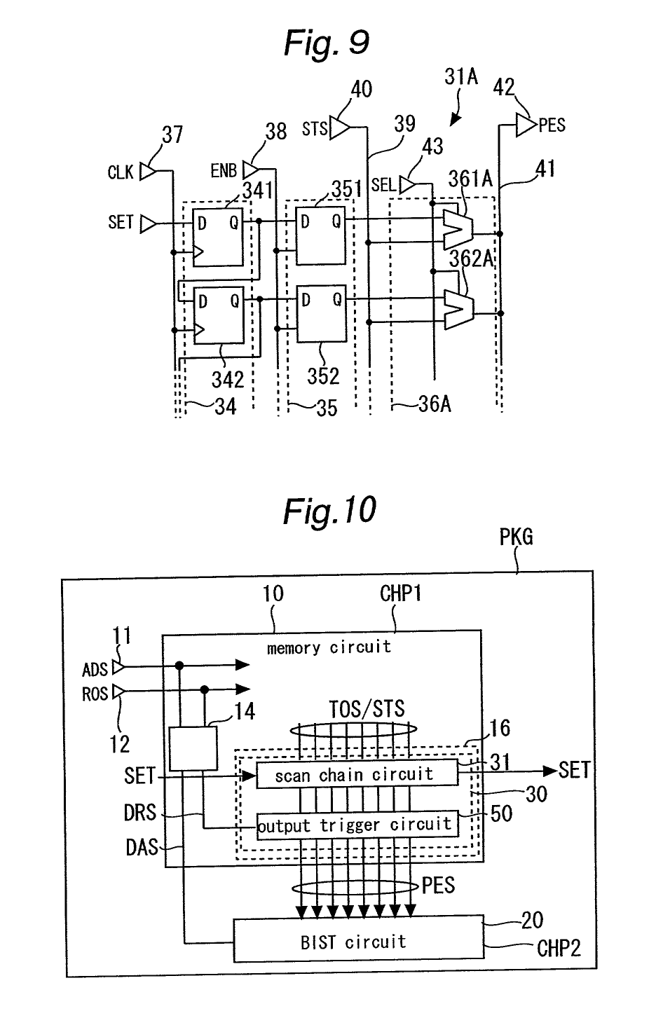

FIG. 9 is a circuit diagram showing a scan chain circuit 31A used by a second embodiment of the test circuit for a semiconductor memory according to the present invention. This second embodiment also indicates a second embodiment of the semiconductor memory device according to the present invention. The scan chain circuit 31A is formed on a chip on which the memory circuit 10 and the BIST circuit 20 are formed. The scan chain circuit 31A is similar to the scan chain circuit 31 shown in FIG. 3. However, the scan chain circuit 31A uses a logic gate circuit 36A instead of the logic gate circuit 36 of FIG. 3. The other components are the same as those shown in FIG. 3, and therefore denoted by like numerals.

The logic gate circuit 36A includes selector circuits 361A, 362A, and so on, each corresponding to one of the n bits. One input of each of the selector circuits 361A, 362A, and so on, is connected to the Q output terminal of the respective one of the DQ flip-flops 351, 352, and so on, in the half latch 35. The other input of each of the selector circuits 361A, 362A, and so on, is connected to the input terminal 40 for the standard test signal STS through the bus line 39. The output terminal of each of the selector circuits 361A, 362A, and so on, is connected to the output terminal 42 for the pseudo-error signal PES through the bus line 41. Furthermore, each of the selector circuits 361A, 362A, and so on, has a select terminal commonly connected to an input terminal 43 for a select signal SEL, and outputs the pseudo-error signal PES when the select signal SEL rises.

The exclusive OR circuits 361, 362, and so on, used in the logic gate circuit 36 of FIG. 3 inverts the signal of the Q output terminal of each of the DQ flip-flops 351, 352, and so on, in the half latch 35 to convert the standard test signal STS. In contrast, the selector circuits 361A, 362A, and so on, of FIG. 9 outputs the signal of the Q output terminal of each of the DQ flip-flops 351, 352, and so on, as it was entered to convert the standard test signal STS. For example, if setting signal SET set in the half latch 35 is “01010101”, the same signal “01010101” is output as the pseudo-error signal PES. Both the logic gate circuit 36 of FIG. 3 and the logic gate circuit 36A of FIG. 9 can be used to generate the pseudo-error signal PES obtained as a result of converting the standard test signal STS based on the setting signal SET. Furthermore, it is possible to easily change the pseudo-error signal PES by changing the setting signal SET.

### Third Embodiment

FIG. 10 is a block circuit diagram showing a third embodiment of the test circuit for a semiconductor memory according to the present invention. This third embodiment also indicates a third embodiment of the semiconductor memory device according to the present invention. In the third embodiment, the memory circuit 10 is formed on a first semiconductor chip CHP1, and the BIST circuit 20 is formed on another chip, namely a second semiconductor chip CHP2. The first and second semiconductor chips CHP1 and CHP2 are packaged in a single plastic package PKG, constituting a semiconductor memory device.

In the third embodiment shown in FIG. 10, the pseudo-error signal generating circuit 30 is formed on the semiconductor chip CHP1 on which the memory circuit 10 is formed. Specifically, the pseudo-error signal generating circuit 30 is formed together with the output buffer 13 of the memory circuit 10 in an area 16 in which the output buffer 13 is formed. The pseudo-error signal generating circuit 30 receives the test signal STS from the output buffer 13 and outputs the pseudo-error signal PES. The pseudo-error signal generating circuit 30 is configured in the same way as the first or second embodiment.

In the third embodiment, the memory circuit 10 is formed on the chip CHP1 and the BIST circuit 20 is formed on another chip, namely CHP2. That is, the package PKG has a multichip configuration. However, the semiconductor memory device as a whole is still configured as the single small package PKG. The pseudo-error signal generating circuit 30 is formed on the chip CHP1 on which the memory circuit 10 is formed, which eliminates the need for increasing the number of chips to be employed for the pseudo-error signal generating circuit 30.

### Fourth Embodiment

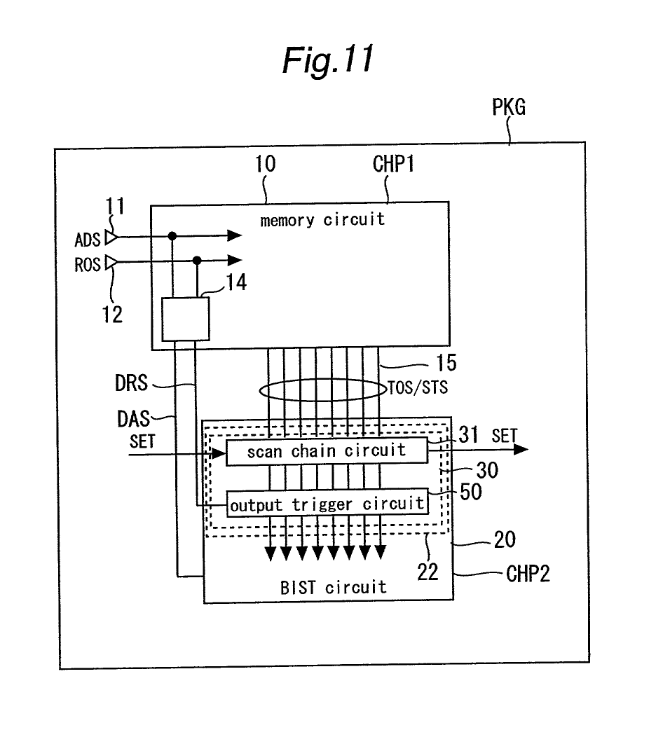

FIG. 11 is a block circuit diagram showing a fourth embodiment of the test circuit for a semiconductor memory according to the present invention. This fourth embodiment also indicates a fourth embodiment of the semiconductor memory device according to the present invention. In the fourth embodiment, as in the third embodiment, the memory circuit 10 is formed on the first semiconductor chip CHP1, and the BIST circuit 20 is formed on another semiconductor chip, namely CHP2. The first and second semiconductor chips CHP1 and CHP2 are packaged in the single package PKG, constituting a semiconductor memory device.

In the fourth embodiment shown in FIG. 11, the pseudo-error signal generating circuit 30 is formed on the semiconductor chip CHP2 on which the BIST circuit 20 is formed. The pseudo-error signal generating circuit 30 is formed in an area 22 for the input buffer circuit in the BIST circuit 20. The pseudo-error signal generating circuit 30 receives the test signal STS from the output buffer circuit 13 and outputs the pseudo-error signal PES. The pseudo-error signal generating circuit 30 is configured in the same way as the first or second embodiment.

In the fourth embodiment, the memory circuit 10 is formed on the chip CHP1 and the BIST circuit 20 is formed on another chip, namely CHP2. That is, the package PKG has a multichip configuration. However, the semiconductor memory device as a whole is still configured as the single small package PKG. The pseudo-error signal generating circuit 30 is formed on the chip CHP2 on which the BIST circuit 20 is formed, which eliminates the need for increasing the number of chips to be employed for the pseudo-error signal generating circuit 30.

### Fifth Embodiment

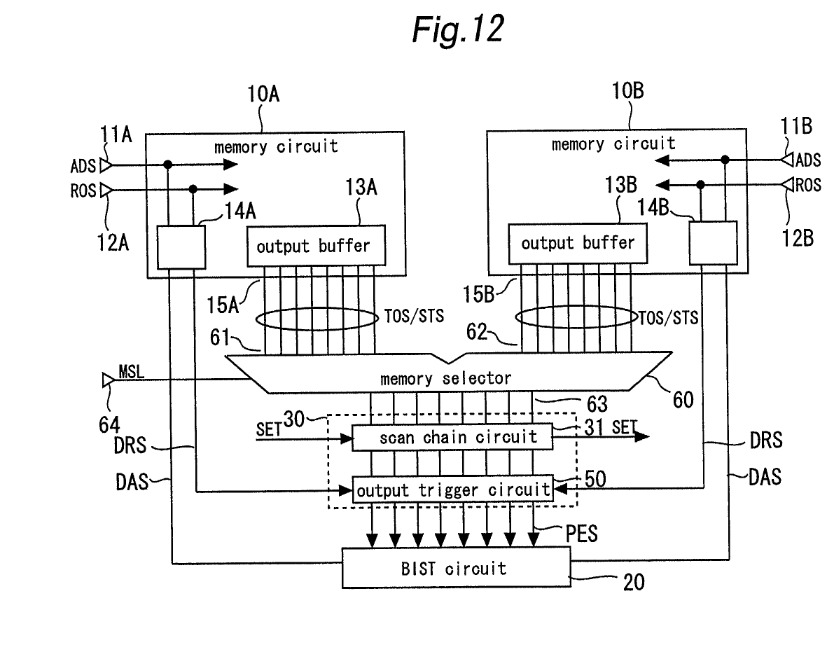

FIG. 12 is a block circuit diagram showing a fifth embodiment of the test circuit for a semiconductor memory according to the present invention. This fifth embodiment also indicates a fifth embodiment of the semiconductor memory device according to the present invention. The fifth embodiment has two memory circuits 10A and 10B. The memory circuits 10A and 10B are each configured in the same way as the memory circuit 10 shown in FIG. 1, and have a large number of memory elements therein. The memory circuit 10A has: an input terminal 11A for receiving the address signal ADS; an input terminal 12A for receiving the read-out signal ROS; an output buffer circuit 13A; and a delay circuit 14A for generating the delay read-out signal DRS and the delay address signal DAS. Similarly, the memory circuit 10B has: an input terminal 11B for receiving the address signal ADS; an input terminal 12B for receiving the read-out signal ROS; an output buffer circuit 13B; and a delay circuit 14B for generating the read-out signal DRS and the delay address signal DAS.

The output buffer circuit 13A of the memory circuit 10A and the output buffer circuit 13B of the memory circuit 10B generate the test output TOS on output terminals 15A and 15B, respectively. The test output TOS is set as the standard test signal STS in the case of generation of the pseudo-error signal PES. The fifth embodiment employs a memory selector 60 for selecting between the outputs of the memory circuits 10A and 10B. The memory selector 60 has: a first input terminal 61 connected to the output terminal 15A of the memory circuit 10A; a second input terminal 62 connected to the output terminal 15B of the memory circuit 10B; and a common output terminal 63. The output terminal 63 is connected to the input terminal 40 of the scan chain circuit 31 in the pseudo-error signal generating circuit 30, and further connected to the logic gate circuits 36 and 36A through the bus line 39. The memory selector 60 has an input terminal 64 for receiving a memory select signal MSL.

In the fifth embodiment shown in FIG. 12, the BIST circuit 20 has a function to selectively test the memory circuits 10A and 10B. One of the memory circuits 10A and 10B is selected based on the memory select signal MSL on the input terminal 64, and the test output TOS of the selected memory circuit 10A or 10B is input to the BIST circuit 20 to check the operation of the memory elements. It is possible to verify the operation of the BIST circuit 20 regardless of whether the memory circuit 10A or 10B has been selected. The operation of the BIST circuit 20 is verified as follows. The standard test signal STS is output from either the selected memory circuit 10A or 10B and converted based on the setting signal SET to generate the pseudo-error signal PES. The generated pseudo-error signal PES is supplied to the BIST circuit 20.

The fifth embodiment shown in FIG. 12 indicates a semiconductor memory device having a single-chip configuration. All of the two memory circuits 10A and 10B, the BIST circuit 20, the pseudo-error signal generating circuit 30, and the memory selector 60 are formed on a single semiconductor chip and packaged. The one-chip configuration of the fifth embodiment makes it possible to miniaturize the semiconductor device. Furthermore, in the fifth embodiment, the two memory circuits 10A and 10B are selectively tested, and the operation of the BIST circuit 20 can be verified regardless of whether the memory circuit 10A or 10B has been selected. It should be noted that the logic gate circuit 36 of FIG. 3 or the logic gate circuit 36A of FIG. 9 is used as the scan chain circuit 31.

### Sixth Embodiment

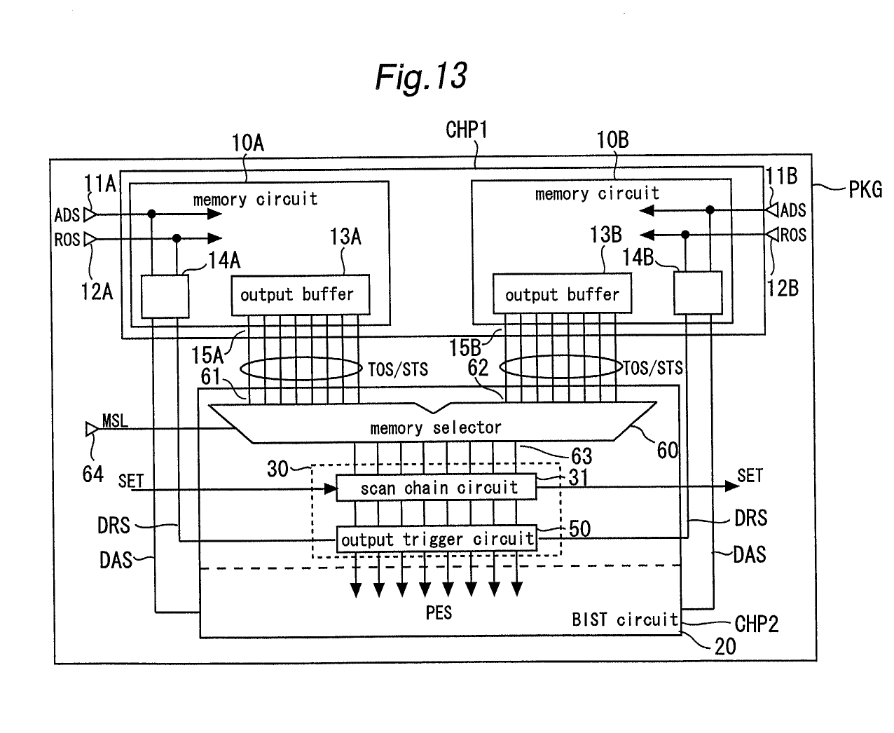

FIG. 13 is a block circuit diagram showing a sixth embodiment of the test circuit for a semiconductor memory according to the present invention. This sixth embodiment also indicates a sixth embodiment of the semiconductor memory device according to the present invention. The sixth embodiment, like the fifth embodiment, has the two memory circuits 10A and 10B, and the memory selector 60. However, the sixth embodiment has a chip configuration different from that of the fifth embodiment. The memory circuits 10A and 10B are formed on a first chip CHP1, while the BIST circuit 20, the pseudo-error signal generating circuit 30, and the memory selector 60 are formed on a second chip CHP2. The first and second chips CHP1 and CHP2 are packaged in a single package PKG.

The two-chip one-package configuration of the sixth embodiment makes it possible to miniaturize the semiconductor device. Furthermore, in the sixth embodiment, the two memory circuits 10A and 10B are selectively tested, and the operation of the BIST circuit 20 can be verified regardless of whether the memory circuit 10A or 10B has been selected.

### Seventh Embodiment

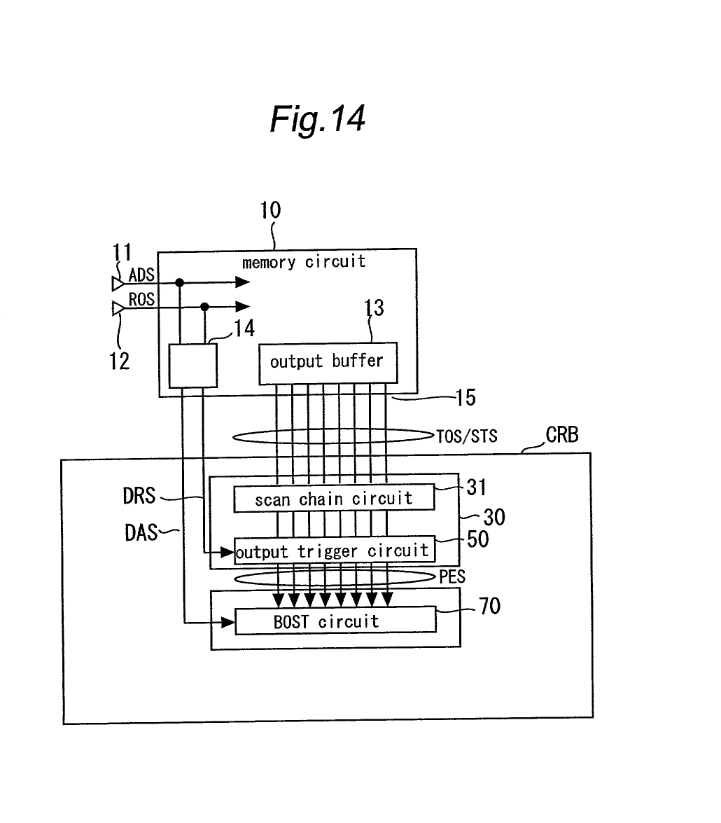

FIG. 14 is a block circuit diagram showing a seventh embodiment of the test circuit for a semiconductor memory according to the present invention. The seventh embodiment uses a built-out self-test circuit (BOST circuit) 70 as its self-test circuit.

In the seventh embodiment, on a circuit board CRB called “a performance board” constituting a part of the tester, the built-out self-test circuit (BOST circuit) 70 and the pseudo-error signal generating circuit 30 for generating the pseudo-error signal PES are disposed.

The circuit configuration of the seventh embodiment is the same as that of the first embodiment shown in FIG. 1. The pseudo-error signal generating circuit 30 is wired so that it receives a test output from the output buffer circuit 13 of the memory circuit 10. The pseudo-error signal generating circuit 30 is configured in the same way as the first embodiment shown in FIG. 1, and converts the standard test signal STS supplied from the memory circuit 10 into the pseudo-error signal PES based on the setting signal SET and supplies the pseudo-error signal PES to the BOST circuit 70. The pseudo-error signal PES is used to verify the operation of the BOST circuit 70. The seventh embodiment makes it possible to verify the operation of the BOST circuit 70 without adversely affecting the operation of the memory circuit 10. It should be noted that the logic gate circuit 36A shown in FIG. 9 can be used as the logic gate circuit of the pseudo-error signal generating circuit 30.

### Eighth Embodiment

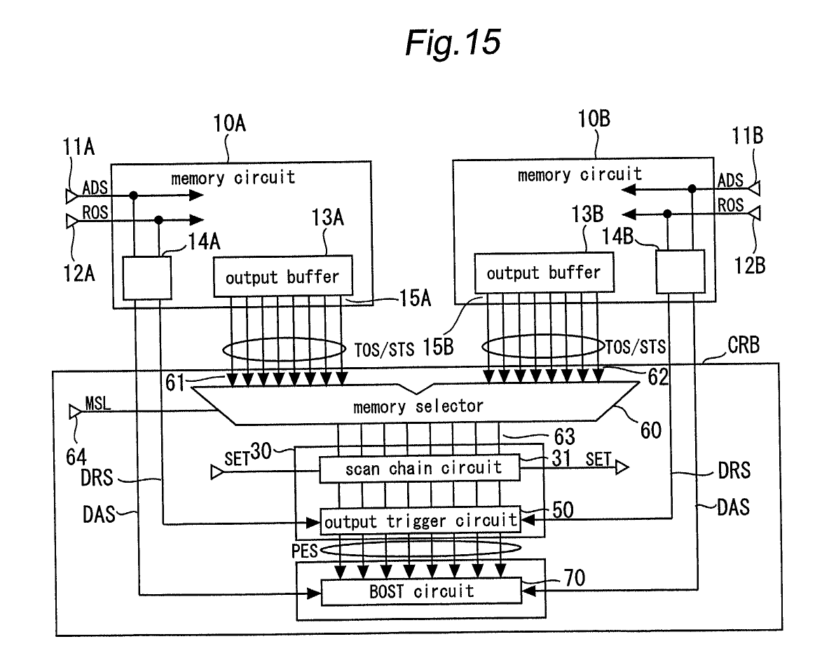

FIG. 15 is a block circuit diagram showing an eighth embodiment of the test circuit for a semiconductor memory according to the present invention. In the eighth embodiment, the BOST circuit 70, the pseudo-error signal generating circuit 30, and memory selector 60 are disposed on the circuit board CRB. As in the seventh embodiment, the BOST circuit 70 selects and tests one of the memory circuits 10A and 10B. The pseudo-error signal generating circuit 30, like the one shown in FIG. 12 or 13, converts the standard test signal STS supplied from the memory test circuit 10A or 10B selected by memory selector 60, based on the setting signal SET to generate the pseudo-error signal PES, and supplies the pseudo-error signal PES to the BOST circuit 70 to verify the operation of the BOST circuit 70. In the eighth embodiment, the BOST circuit 70 is used to selectively test the two memory circuits 10A and 10B, and the operation of the BOST circuit 70 can be verified regardless of whether the memory circuit 10A or 10B has been selected, without adversely affecting the operation of the memory circuits 10A and 10B.

It should be noted that even though the above fifth, sixth, and eighth embodiments employ two memory circuits, a case in which three or more memory circuits are employed can be applied to the present invention.

The features and the advantages of the present invention as described above may be summarized as follows.

According to one aspect of the invention, the test circuit for a semiconductor memory employs a pseudo-error signal generating circuit between a memory circuit and a self-test circuit. Accordingly, the operation of the self-test circuit can be easily verified by generating a pseudo-error signal by use of the pseudo-error signal generating circuit. Furthermore, the pseudo-error signal generating circuit generates the pseudo-error signal by converting the output signal of the memory circuit. Accordingly, the operation of the self-test circuit can be verified without adversely affecting the memory circuit. Furthermore, in the embodiments in which the output signal of the memory circuit is converted based on a setting signal to generate the pseudo-error signal. The pseudo-error signal can be changed easily by changing the setting signal.

In another aspect, the semiconductor memory device also employs a pseudo-error signal generating circuit between a memory circuit and a self-test circuit. The operation of the self-test circuit can be verified easily by generating a pseudo-error signal by use of the pseudo-error signal generating circuit. Furthermore, the pseudo-error signal generating circuit generates the pseudo-error signal by converting the output signal of the memory circuit. Accordingly, the operation of the self-test circuit can be verified without adversely affecting the memory circuit. Furthermore, in the embodiments in which the output signal of the memory circuit is converted based on a setting signal to generate the pseudo-error signal the pseudo-error signal can be changed easily by changing the setting signal.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-224900, filed on Jul. 25, 2001 including specification, claims, drawings and summary, on which the Convention priority of the present application is based, are incorporated herein by reference in its entirety.

1. A test circuit for a semiconductor memory, said test circuit comprising:
a built-out self-test circuit connected to a memory circuit of semiconductor memory, said self-test circuit receiving an output signal of said memory circuit to test said memory circuit; and
a pseudo-error signal generating circuit provided between said memory circuit and said built-out self-test circuit, said pseudo-error signal generating circuit generating a pseudo-error signal to verify operation of said built-out self-test circuit;
wherein said pseudo-error signal generating circuit converts an output signal of said memory circuit to generate said pseudo-error signal.

2. A semiconductor memory device comprising:
a memory circuit;
a self-test circuit connected to said memory circuit; and
a pseudo-error signal generating circuit provided between said memory circuit and said self-test circuit, said pseudo-error signal generating circuit generating a pseudo-error signal to verify operation of said self-test circuit;
wherein said pseudo-error signal generating circuit converts an output signal of said memory circuit to generate said pseudo-error signal.

3. The semiconductor memory device according to claim 2, wherein said self-test circuit is a built-in self-test circuit, and formed on a chip on which said memory circuit is formed.

4. The semiconductor memory device according to claim 2, wherein said self-test circuit is a built-in self-test circuit, and both said self-test circuit and said pseudo-error signal generating circuit are formed on a chip on which said memory circuit is formed.

5. The semiconductor memory device according to claim 2, wherein said self-test circuit is a built-in self-test circuit, and said memory circuit is formed on one chip whereas said self-test circuit is formed on another chip, said one chip and said another chip being packaged in a single package.

6. The semiconductor memory device according to claim 2, wherein said memory circuit has an output buffer, and said pseudo-error signal generating circuit converts an output signal of said output buffer based on a setting signal to generate said pseudo-error signal.

7. The semiconductor memory device according to claim 2, wherein said pseudo-error signal generating circuit has a scan chain circuit, and converts an output signal of said memory circuit based on a setting signal set in said scan chain circuit to generate said pseudo-error signal.

8. The semiconductor memory device according to claim 7, wherein said pseudo-error signal generating circuit has a logic gate circuit for receiving an output signal of said memory circuit and an output of said scan chain circuit, and said logic gate circuit converts said output signal of said memory circuit based on a setting signal of said scan chain circuit to output said pseudo-error signal.

9. The semiconductor memory device according to claim 2, wherein said pseudo-error signal generating circuit has a trigger circuit which outputs said pseudo-error signal to said self-test circuit based on a read-out signal for said memory circuit.

10. The semiconductor memory device according to claim 2, wherein said pseudo-error signal generating circuit generates a pseudo-error signal pattern including a plurality of pseudo-error signals while changing a setting signal of said scan chain circuit.

11. The semiconductor memory device according to claim 2, further comprising:
a plurality of said memory circuits; and
a memory selector for selecting among output signals of said plurality of said memory circuits;
wherein an output signal of said memory selector is supplied to said pseudo-error signal generating circuit.
